(19) United States
(12) Patent Application Publication
(10) Pub. No.: US 2026/0313811 A1
(43) Pub. Date: Oct. 8, 2026

(54) METHOD OF FORMING AN ELECTRONIC ASSEMBLY HAVING A CONFORMAL COATING, ELECTRONIC ASSEMBLY AND FILM PRECURSOR TO CONFORMAL COATING

(71) Applicant: H. K. WENTWORTH LIMITED, Surrey (GB)

(72) Inventor: Phil KINNER, Surrey (GB)

(21) Appl. No.: 19/100,821

(22) PCT Filed: Aug. 4, 2023
(86) PCT No.: PCT/EP2023/025367

§ 371 Date: Feb. 3, 2025

(30) Foreign Application Priority Data
Aug. 10, 2022 (GB) 2211698.2

(51) Int. Cl. H05K 3/28; H05K 3/3478; H05K 3/3485; H05K 3/3494

(52) U.S. Cl. CPC H05K 3/284; H05K 3/285; H05K 3/3478; H05K 3/3485; H05K 3/3494; H05K 2203/043; H05K 2203/1316

(57) ABSTRACT

The present invention provides a method of forming an electronic assembly having a conformal coating, the method comprising: providing an assembly preform, the assembly preform comprising solder paste located between a substrate and an electronic component; providing a film in solid form in the vicinity of the assembly preform, the film comprising a polymer material; heating the solder paste to reflow the solder paste to form a solder joint between the substrate and the electronic component; and heating the film in the vicinity of the assembly preform to adhere the film to the assembly preform to form a conformal coating that at least partially coats the electronic component.

The present invention relates to a method of forming an electronic assembly having a conformal coating and a film for use as a precursor to a conformal coating of an electronic assembly.

A conformal coating is a coating that may be formed over the components of an electronic assembly, for example, for the purpose of providing a physical layer of protection for the assembly from environmental factors, such as humidity, condensation, salt-spray and corrosive gases, for example.

Conventional methods of forming conformal coatings on electronic assemblies include liquid applied coatings, vacuum applied materials (such as in batch processes) and two-component coatings (such as foams, UV curable compositions and room-temperature-vulcanising (RTV) silicone).

The most common methods of forming conformal coatings on electronic assemblies involve the application of liquid applied coatings, by dip, spray, dispensing or other methods suitable for the controlled application of the liquid coating. Such methods may also involve providing a coating precursor in pellet or stick form, which is then melted and dispensed onto the substrate or circuit board. Dispensing the melted coating precursor may involve spraying the melted coating precursor onto the area to be coated, for example. Dipping and brushing techniques are also known. The coating may then further be dried or cured by a variety of methods including the application of heat, radiation, chemical reaction or simple solvent-evaporation.

However, problems with such coating processes may include that dispensing the liquid coating requires additional process time and equipment, and can lead to challenges with coverage and thickness uniformity; that accuracy of the coating placement may not be sufficient; that curing the liquid applied coatings generally requires further energy input, which, as well as being inefficient, can reduce the lifetime of the coated assembly; and that many of the materials used for such liquid applied coatings contain hazardous solvents or other ingredients which are released to the environment, posing a threat to users and the environment. Moreover, further additional pre-coating steps may be required, such as cleaning, masking or taping to prevent coating of unwanted surfaces.

For example, U.S. Pat. No. 5,510,138A discloses a similar hot melt conformal coating process. In U.S. Pat. No. 5,510,138A, the conformal coating system is a liquid at an elevated temperature at which the coating systems are applied to an electronic assembly. In other words, the hot liquid coating is applied to the substrate at the elevated temperature, where it solidifies with cooling. Optionally, a further cross-linking mechanism can be incorporated which may require additional energy input. Thus, the above-outlined disadvantages of additional processing and energy inputs may apply.

US 2017/0309799A1 relates to a vacuum lamination method for forming a conformally coated article and associated conformally coated articles formed therefrom. U.S. Pat. No. 5,475,379A relates to a solid phase conformal coating suitable for use with electronic devices. WO 95/28822A1 relates to a conformal shield and a method for forming the same. U.S. Pat. No. 5,102,712A relates to a process for the conformal coating of printed circuit boards. U.S. Pat. No. 9,900,988B1 relates to a protective layering process for circuit board EMU shielding and thermal management. US 2018/0211848A1 relates to an electronic product and a manufacturing method thereof. U.S. Pat. No. 10,568,215A relates to PCBA encapsulation by thermoforming. US 2003/0193113A1 relates to an apparatus and method for protecting an electronic circuit. US 2020/0267844A1 relates to an adhesive circuit patterning process.

Accordingly, there is a need to provide an improved method of forming a conformal coating on an electronic assembly, the method being more time- and energy-efficient, as well as being simpler and preferably reducing the number of process steps.

The present invention seeks to tackle at least some of the problems associated with the prior art or at least to provide a commercially acceptable alternative solution thereto.

The present invention provides a method of forming an electronic assembly having a conformal coating and a film for use as a precursor to a conformal coating of an electronic assembly according to the claims appended hereto.

Specifically, in a first aspect the present invention provides a method of forming an electronic assembly having a conformal coating, the method comprising: providing an assembly preform, the assembly preform comprising solder paste located between a substrate and an electronic component; providing a film in solid form in the vicinity of the assembly preform, the film comprising a polymer material; heating the solder paste to reflow the solder paste to form a solder joint between the substrate and the electronic component; and heating the film in the vicinity of the assembly preform to adhere the film to the assembly preform to form a conformal coating that at least partially coats the electronic component.

Each aspect or embodiment as defined herein may be combined with any other aspect(s) or embodiment(s) unless clearly indicated to the contrary. In particular, any features indicated as being preferred or advantageous may be combined with any other feature indicated as being preferred or advantageous.

The Inventor has surprisingly found that it is possible to form an electronic assembly having a conformal coating by the method of the present invention. In particular, it has surprisingly been found that a conformal coating can be provided by providing a film in solid form in the vicinity of the assembly preform, and heating the film in the vicinity of the assembly preform to adhere the film to the assembly preform to form a conformal coating that at least partially coats the electronic component. Moreover, it has been found that such a method may exhibit certain advantages over the conventional methods of forming conformal coatings.

In particular, such a method may surprisingly avoid the need for additional process steps and equipment requirements (e.g. dispensing, buffering and curing/drying); utilise existing processes (e.g. reflow profile); minimise thermal degradation of components/assemblies; improve coverage and uniformity of the coating; and also avoid the need for some pre-coating process steps, such as masking or taping to prevent coating of unwanted surfaces. The present invention takes away the requirement to dispense the material, e.g. in liquid form.

Moreover, advantageously, such a method may also avoid the use of solvents (due to not being applied in liquid form), which may be toxic. This is because the polymer material film being handled generally has low toxicity. In addition, placement of the film in solid form can be fast and accurate, particularly in comparison to liquid application methods. Since existing equipment and similar processes can be used for the reflow profile, this may also eliminate the need for additional steps.

Such a method may also advantageously eliminate mess and hazardous waste from handling liquid products, reduce health and safety demands, save space needed for additional equipment (e.g. a hold melt coating applicator) and therefore also reduce energy consumption of the overall process.

The term “electronic assembly” as used herein may encompass a system or device comprising a one or more electronic components electronically connected to one another and configured to perform a function. Electronic assembly is a term of art known to the skilled person. For example, an electronic assembly may comprise a printed circuit board (PCB) having one or more electronic components mounted thereon.

The term “conformal coating” as used herein may generally encompass a thin layer of polymeric material that may cover an electronic assembly, typically conforming to the contours or topography of the electronic assembly, in order to help protect, physically, the components and/or substrate of the electronic assembly, for example against moisture, dust, chemicals and/or temperature extremes. Conformal coatings, in general, are well known to the skilled person.

The term “assembly preform” as used herein may encompass a precursor to an electronic assembly, for example, in which the one or more electronic components are arranged in their desired position(s), but in which the solder paste has not yet been reflowed.

The term “solder paste” as used herein may encompass a solder powder mixed with flux, for example. Solder pastes are well known to the skilled person and the type of solder paste used is not particularly limited for the purpose of the invention. However, preferably, the solder paste contains substantially no rosin or resin, more preferably the solder paste is free of rosin or resin. It may also be possible to use a sintering power or soldering film in place of the solder paste, for example.

The term “substrate” as used herein may encompass any object in which electronic components may typically be mounted, for example a PCB. A substrate may typically comprise an electrically insulating plastics material, for example. Suitable substrates are known to the skilled person.

The term “electronic component” as used herein may encompass any basic discrete device or physical entity in an electronic system used to affect electrons or their associated fields. A non-exhaustive list of electronic components includes resistors, capacitors, light-emitting diodes, transistors, Field Effect Transformers (FETS), Bottom Terminated Components (BTCs), Metal Electrode Leadless Face (MELFs), Small Outline Integrated Circuit (SOIC) and Quad Flat Packages (QFPs), for example. However, the type of electronic component is not important for the purposes of the present invention.

The solder paste is located between the substrate and the electronic component. However, as will be appreciated by the skilled person, the solder paste may not be only located directly between the substrate and the electronic component. For example, the solder paste may also be located around the electronic component.

The term “film” as used herein may encompass a layer or sheet, typically a thin layer or sheet (for example, from about 30 μm to about 1 mm (or greater) in thickness). The film may be flat, i.e. planar, or more typically have at three-dimensional shape, such as to conform to the contours of the component over which it is placed. The film is in solid form, and may substantially retain its shape at room temperature, such as at about 20° C. However, the film may also be flexible. Preferably, the film consists essentially of, or more preferably consists of, the polymer material. The term “consists essentially of” as used herein may encompass that specific further components can be present, namely those not materially affecting the essential characteristics of the film.

Providing a film in solid form in the vicinity of the assembly preform may encompass providing the film in solid form at a location at or near to the intended location of the conformal coating to be formed, for example. For example, the film may be provided opposite (and facing) the face of the substrate on which the electronic component is provided, and preferably substantially parallel, more preferably parallel, to the face of the substrate on which the electronic component is provided. In other words, the film may be provided in solid form in the vicinity of the electronic component and/or the substrate. The term “in the vicinity” in this context may encompass a shortest distance between the objects of from 0 to 50 mm, preferably from 0 to 20 mm, more preferably from 0 to 10 mm, even more preferably from 0.01 to 5 mm, and still more preferably from 0.05 to 2 mm, for example. A shortest distance between the objects of 0 mm may encompass that the objects are in contact with one another. The term “in solid form” as used herein may encompass that the film is a solid when provided in the vicinity of the assembly preform.

The polymer material may typically exhibit a high thermal stability, and also be highly electrically insulating, once the conformal coating has been formed.

The term “solder joint” as used herein may encompass a solid attachment formed between the substrate and the electronic component upon cooling of the reflowed solder paste, for example.

The term “coats” as used herein may encompass both directly coating the electronic component (for example being in direct contact with the electronic component) and/or indirectly coating the electronic component (for example providing a physical barrier between the electronic component and the environment, without physically contacting the electronic component).

Typically, the step of heating the film in the vicinity of the assembly preform to adhere the film to the assembly preform may involve heating the film to soften and/or melt the film, which then may adhere to the assembly preform while maintaining the required topographical coverage. In other words, the adhered film may become the conformal coating.

As will be clear from the description of the invention outlined herein, the step of heating the film in the vicinity of the assembly preform is performed after the step of providing a film in solid form in the vicinity of the assembly preform. In other words, the film may be softened or melted, for example, in situ. However, unless otherwise specified, in the broadest embodiment of the invention the step of heating the solder paste to reflow the solder paste may be performed at any time after the step of providing an assembly preform.

In one preferred embodiment, the film and the solder paste are heated simultaneously. Preferably, the solder paste is reflowed after heating the film in the vicinity of the assembly preform to adhere the film to the assembly preform. The film and the solder paste being heated simultaneously may be compatible with the embodiment in which the solder paste is reflowed after heating the film in the vicinity of the assembly preform to adhere the film to the assembly preform, for example, if the solder paste has a higher reflow temperature than the softening temperature of the film. That is, even if the solder paste is heated simultaneously with the film, the solder paste may reflow after the film is heated. More preferably, the solder paste is reflowed whilst heating the film in the vicinity of the assembly preform to adhere the film to the assembly preform. In other words, preferably, the heat from the soldering process is used to simultaneously melt the film in place. Advantageously, such methods may provide further improvements on the broadest embodiment of the invention and compared to the methods of the prior art. This is because further process steps, namely further additional heating steps, for example, can be avoided. Such a method of forming a conformal coating may therefore be extremely efficient. This is because the coating can be applied without the need to first reflow the solder paste, saving time, energy and costs. In other words, the method may preferably involve a single heating step, which can both cause reflow of the solder paste to form the solder joint, and cause the film to adhere to the assembly preform to form the conformal coating.

In an alternative preferred embodiment, heating the solder paste takes place prior to providing a film in solid form in the vicinity of the assembly preform, i.e. the assembly preform on which the solder paste has already been reflowed. In other words, in this embodiment reflowing (or solidifying) the solder paste preferably takes place prior to providing a film in solid form in the vicinity of the assembly preform. In other words, in this embodiment the solder joint is preferably formed prior to forming the conformal coating on the assembly preform (i.e. adhering the film to the assembly preform). It will, of course, be appreciated that since the solder paste has already been reflowed at the time of providing the film in solid form, it may be said that the film is provided in solid form in the vicinity of the assembly preform on which the solder paste has been reflowed, i.e. now in the form of an electronic assembly (i.e. the electronic assembly provided by heating the solder paste to reflow the solder paste to form a solder joint between the substrate and the electronic component). Preferably, heating the solder paste takes place prior to heating the film in the vicinity of the assembly preform (or resulting electronic assembly, as the case may be). This may be possible because, generally, the melting point of the film may be lower than the melting point of the solder joint, for example. This embodiment may be more preferred when, for example, “weak” solders are used, in order to reduce the risk of “hot tear” defects in the solder joints, for example. However, the alternative embodiment described above may be more preferred, since it may require less time- and energy-input, as described herein.

In other words, in this alternative preferred embodiment, the present invention provides a method of forming an electronic assembly having a conformal coating, the method comprising:
providing an assembly preform, the assembly preform comprising solder paste located between a substrate and an electronic component;
heating the solder paste to reflow the solder paste to form a solder joint between the substrate and the electronic component (i.e. to form an electronic assembly);
providing a film in solid form in the vicinity of the assembly preform on which the solder paste has been reflowed (i.e. the electronic assembly), the film comprising a polymer material; and
heating the film in the vicinity of the assembly preform on which the solder paste has been reflowed (i.e. the electronic assembly) to adhere the film to the assembly preform on which the solder paste has been reflowed (i.e. the electronic assembly) to form a conformal coating that at least partially coats the electronic component. The assembly preform on which the solder paste has been reflowed may encompass an electronic assembly.

Preferably, providing a film in solid form in the vicinity of the assembly preform comprises providing the film in solid form and at a non-elevated temperature, preferably at room temperature. The term “non-elevated temperature” as used herein may encompass that the film is not intentionally nor purposefully heated when the film is (initially) provided in solid form in the vicinity of the assembly preform. In other words, the term “elevated” may be relative to room temperature. As such, the film may have a temperature of from about 10 to about 30° C., for example, more preferably from about 15 to about 25° C., more preferably about 20° C., at or during this step of the method. This means that the film may be simply provided in solid form, and that no additional heating steps are required. This may reduce the complexity of the method, as well as reduce the time, energy and cost requirements of forming the conformal coating.

Preferably, heating the film in the vicinity of the assembly preform to adhere the film to the assembly preform comprises adhering the film to the substrate of the assembly preform. In other words, the film is preferably adhered to the substrate of the assembly preform to form the conformal coating. Such an arrangement may advantageously form a secure conformal coating. Alternatively or additionally, heating the film in the vicinity of the assembly preform to adhere the film to the assembly preform may comprise adhering the film to an electronic component of the assembly preform.

Preferably, the conformal coating at least partially coats the solder joint, more preferably the conformal coating fully coats the solder joint. Such a conformal coating may provide the best protection for the electronic assembly.

Preferably, the conformal coating fully encapsulates the electronic component between the film and the substrate. The term “fully encapsulates” as used herein may encompass that the electronic component is fully surrounded (either directly or indirectly) by a combination of the substrate and the conformal coating (i.e. the adhered film). In other words, the film preferably forms a tent-like shape over the electronic component, with the base of the tent-like shape being in contact with the substrate. As such, the conformal coating therefore also preferably fully encapsulates the solder joint. Such a conformal coating may provide the best protection for the electronic assembly.

Preferably, heating the solder paste comprises heating the assembly preform. In other words, to heat the solder paste, it may be required to heat the entire assembly preform. Alternatively, the solder paste may be heated directly. The method of heating the solder paste is not particularly limited and nor is the method of heating the film. Heating the assembly preform may also include at the same time heating the film in the vicinity of the assembly preform.

Preferably, providing a film in solid form in the vicinity of the assembly preform comprises contacting the assembly preform with the film in solid form, more preferably contacting the substrate of the assembly preform with the film in solid form. The film may also contact an electronic component of the assembly preform. Directly contacting the assembly preform with the film may assist in the adhesion of the film to the assembly preform.

Preferably, heating the film comprises softening and/or at least partially melting the film. Softening and/or at least partially melting the film may assist in the adhesion of the film to the assembly preform. Softening and/or at least partially melting the film may also assist in conforming the film to the contours of the assembly preform, in order to obtain a more efficient and desirable coating. The rheology of the melted film may advantageously assist in keeping the film in the desired location on the assembly preform or electronic assembly during the heating step, conforming to the contours of the assembly preform or electronic assembly.

Preferably, the polymer material is a thermoplastic material. Thus, it may be possible to heat the conformal coating to allow easy removal of the conformal coating. This may assist with the recyclability of the electronic assembly, for example.

Alternatively, the polymer material is preferably a thermosetting material. Such materials or plastics may be useful in forming a particularly resilient and resistant conformal coating, for example. Typical thermosetting materials suitable for use in the present invention may include urethane, epoxy, acrylate and silicone moieties. The thermosetting material may be set or cured by any suitable method known to the skilled person, such as, for example, by heat from the reflow-profile, moisture from the environment, and/or UV radiation. The method therefore preferably further comprises curing the polymer material. Curing the polymer material may be typically and preferably performed after forming the conformal coating.

Preferably, the polymer material is cross-linkable. Typical cross-linkable polymer materials suitable for use in the present invention may include urethane, epoxy, acrylate and silicone moieties.

Preferably, the method does not comprise reflowing the solder paste prior to the step of heating the film in the vicinity of the assembly preform. In other words, as described above, the conformal coating is preferably formed before or at the same time as the solder paste is reflowed. This may advantageously reduce the number of methods steps required to form the electronic assembly having the conformal coating.

Preferably, the film is not heated prior to the step of providing a film in solid form in the vicinity of the assembly preform. In other words, the film is preferably not heated immediately prior to the step of providing a film in solid form in the vicinity of the assembly preform. That is, the film is preferably initially provided in solid form in the vicinity of the assembly preform in an unheated state. This does not preclude any heating that may be required when manufacturing the film, such as to mould the film to a particular shape or to form the polymer material, for example. Thus, this may reduce the number of heating steps that the method may require, compared to hot melt coating processes, for example.

Preferably, the film is pre-shaped to be at least partially complementary to the shape of the assembly preform or (resulting) electronic assembly. In other words, the film is preferably configured to be at least partially complementary to the shape of the assembly preform or (resulting) electronic assembly. The film may be at least partially complementary to the shape of at least part of the assembly preform or (resulting) electronic assembly, for example to one or more of the electronic components. The film may also be fully complementary to the assembly preform or (resulting) electronic assembly to be coated. In other words, the film may be formed to the contours of the assembly preform or (resulting) electronic assembly, such as in a three-dimensional manner, as well as being cut to the size of the assembly preform or (resulting) electronic assembly, for example. In other words, the film is preferably provided in a 3-dimensional, pre-formed solid form. Advantageously, the amount of polymer material required may therefore be minimised, and excess material may not be wasted. Moreover, the pre-shaped film may assist in more strongly adhering the film to the assembly preform or electronic assembly, since this may provide a larger surface area of contact between the film and the assembly preform or electronic assembly, for example. Furthermore, less melting/heating of the film may be required, since less movement of the film may be required to obtain the conformal coating. This may therefore save additional time, energy and costs.

More preferably, the film is pre-shaped to be at least partially complementary to the shape of a specific electronic component of the assembly preform or (resulting) electronic assembly. More preferably, the assembly preform comprises a plurality of electronic components, and the method comprises providing plurality of films, wherein a film is provided in solid form in the vicinity of each of the electronic components. In other words, the resulting electronic assembly may comprise a plurality of conformal coatings, each formed from a separate film, each film being pre-shaped to the electronic component or components it will coat. One film may therefore be intended to at least partially coat one or more electronic components. This may also enable the amount of polymer material required to be reduced. Moreover, such a method may enable different compositions of polymer material to be used for the different films, for example. Thus, the coating needs (i.e. dependent on how sensitive the component is to moisture or other environmental factors) can be correlated to the particular electronic component(s) that the film will coat. This may result in a particular effective conformal coating, produced by an efficient method. In other words, the resulting conformal coating may include sub-coatings.

Preferably, the method further comprises pre-shaping the film by die cutting or moulding. Suitable die cutting and moulding methods are known to the skilled person.

Preferably, providing an assembly preform comprises printing and/or dispensing the solder paste on the substrate. Suitable methods of printing the solder paste are known to the skilled person. Preferably, the method further comprises contacting the electronic component with the solder paste, preferably by a pick-and-place method. Pick-and-place methods are known to the skilled person and may encompass, for example, picking the electronic component up from one location (for example using a pick-and-place machine or robot) and placing it in another, such as at the desired location on the solder paste on the substrate, to form the assembly preform.

Preferably, providing a film in solid form in the vicinity of the assembly preform comprises arranging the film by a pick-and-place method. Advantageously, the film can therefore be provided in the desired location quickly and efficiently, thus reducing the time required to form the conformal coating. Arranging the film may comprise locating the film on or at the desired location on the assembly preform.

Preferably, heating the solder paste comprises heating the solder paste to a temperature at or higher than the reflow temperature of the solder paste for from 1 to 5 minutes, such as for from 1 to 3 minutes. Typical solder paste reflow temperatures may be from about 150 to about 250° C., for example. When the film and the solder paste are heated simultaneously, then heating the film and the solder paste may comprise heating the film and the solder paste to or above the softening temperature of the film for from 1 to 5 minutes, such as for from 1 to 3 minutes, for example. Typical softening temperatures of the films of the invention may be from about 130 to about 200° C., for example.

Preferably, the polymer material comprises one or more of a polyolefin, a polyamide, a silicone, a urethane, an epoxy and an acrylic polymer. Suitable polymer materials are known to the skilled person.

Preferably, the assembly preform comprises two or more electronic components.

Preferably, the substrate comprises a printed circuit board. Preferably, the electronic component comprises one or more of a resistor, a capacitor, a light-emitting diode, a transistor, a Field Effect Transformer (FET), a Bottom Terminated Component (BTC), a Metal Electrode Leadless Face (MELF), a Small Outline Integrated Circuit (SOIC) and a quad flat package (QFP). Preferably, the electronic component comprises a QFP.

In a further aspect of the present invention, there is provided an electronic assembly having a conformal coating formed by the method of any preceding claim.

In a further aspect of the present invention, there is provided a film for use as a precursor to a conformal coating of an electronic assembly, the film comprising a polymer material and being pre-shaped to be at least partially complementary to the shape of the assembly preform. That is, the film may be pre-shaped to be at least partially complementary to the shape of an assembly preform for the electronic assembly, the assembly preform comprising solder paste located between a substrate and an electronic component. In other words, the assembly preform may be a precursor to an electronic assembly, for example, in which the one or more electronic components are arranged in their desired position(s), but in which the solder paste has not yet been reflowed, as described herein. In other words, the film may be pre-shaped to be at least partially complementary to the shape of the (resulting) electronic assembly. The preferred embodiments and associated advantages of the film described herein in relation to the first aspect apply equally to the film of this aspect. Such a film may enable the advantages associated with the method described herein to be achieved.

The foregoing detailed description has been provided by way of explanation and illustration, and is not intended to limit the scope of the appended claims. Many variations in the presently preferred embodiments illustrated herein will be apparent to one of ordinary skill in the art and remain within the scope of the appended claims and their equivalents.

1-31. (canceled)

32: A method of forming an electronic assembly having a conformal coating, the method comprising:
providing an assembly preform, the assembly preform comprising solder paste located between a substrate and an electronic component;
providing a film in solid form in the vicinity of the assembly preform, the film comprising a polymer material;
heating the solder paste to reflow the solder paste to form a solder joint between the substrate and the electronic component; and,
heating the film in the vicinity of the assembly preform to adhere the film to the assembly preform to form a conformal coating that at least partially coats the electronic component.

33: The method of claim 32, wherein the film and the solder paste are heated simultaneously.

34: The method of claim 32, wherein the solder paste is reflowed after heating the film in the vicinity of the assembly preform to adhere the film to the assembly preform.

35: The method of claim 32, wherein heating the solder paste takes place prior to providing a film in solid form in the vicinity of the assembly preform.

36: The method of claim 32, wherein providing a film in solid form in the vicinity of the assembly preform comprises providing the film in solid form and at a non-elevated temperature, preferably at room temperature; and/or,
wherein heating the film in the vicinity of the assembly preform to adhere the film to the assembly preform comprises adhering the film to the substrate of the assembly preform.

37: The method claim 32,
wherein the conformal coating at least partially coats the solder joint; and/or,
wherein the conformal coating fully encapsulates the electronic component between the film and the substrate; and/or,
wherein heating the solder paste comprises heating the assembly preform.

38: The method of claim 32, wherein providing a film in solid form in the vicinity of the assembly preform comprises contacting the assembly preform with the film in solid form, preferably contacting the substrate of the assembly preform with the film in solid form.

39: The method of claim 32, wherein heating the film comprises softening and/or at least partially melting the film.

40: The method of claim 32, wherein the polymer material is a thermoplastic material.

41: The method of claim 32, wherein the polymer material is a thermosetting material, preferably wherein the method further comprises curing the polymer material.

42: The method of claim 32, wherein the polymer material is cross-linkable.

43: The method of claim 32, wherein the method does not comprise reflowing the solder paste prior to the step of heating the film in the vicinity of the assembly preform.

44: The method of claim 32, wherein the film is not heated prior to the step of providing a film in solid form in the vicinity of the assembly preform.

45: The method of claim 32, wherein the film is pre-shaped to be at least partially complementary to the shape of the assembly preform, preferably:
wherein the film is pre-shaped to be at least partially complementary to the shape of a specific electronic component of the assembly preform, preferably:
wherein the assembly preform comprises a plurality of electronic components, and the method comprises providing plurality of films, wherein a film is provided in solid form in the vicinity of each of the electronic components.

46: The method of claim 45, wherein the method further comprises pre-shaping the film by die cutting or moulding.

47: The method of claim 32, wherein providing an assembly preform comprises printing and/or dispensing the solder paste on the substrate, preferably wherein the method further comprises contacting the electronic component with the solder paste, preferably by a pick-and-place method.

48: The method of claim 32,
wherein providing a film in solid form in the vicinity of the assembly preform comprises arranging the film by a pick-and-place method; and/or,
wherein heating the solder paste comprises heating the solder paste to a temperature at or higher than the reflow temperature of the solder paste for from 1 to 5 minutes; and/or,
wherein the polymer material comprises one or more of a polyolefin, a polyamide, a silicone, a urethane, an epoxy and an acrylic polymer.

49. The method of claim 32,
wherein the assembly preform comprises two or more electronic components; and/or,
wherein the substrate comprises a printed circuit board; and/or,
wherein the electronic component comprises a quad flat package.

50: An electronic assembly having a conformal coating formed by the method of claim 32.

51: A film for use as a precursor to a conformal coating of an electronic assembly, the film comprising a polymer material and being pre-shaped to be at least partially complementary to the shape of the assembly preform.
